(19) United States
(12) Patent Application Publication
(10) Pub. No.: US 2012/0024368 A1
(43) Pub. Date: Feb. 2, 2012

(54) BACK CONTACTING AND INTERCONNECTION OF TWO SOLAR CELLS

(75) Inventors: Erik Sauar, Oslo (NO); Andreas Bentzen, Oslo (NO)

(73) Assignee: RENEWABLE ENERGY CORPORATION ASA, Sandvika (NO)

(21) Appl. No.: 13/146,868

(22) PCT Filed: Jan. 20, 2010
(86) PCT No.: PCT/NO10/00023

§ 371 Date: Oct. 17, 2011

Related U.S. Application Data
(60) Provisional application No. 61/148,416, filed on Jan. 30, 2009.

(30) Foreign Application Priority Data
Jan. 30, 2009 (GB) 0901605.6

(51) Int. Cl. H01L 31/0224; H01L 31/0232

(52) U.S. Cl. 136/256; 438/65; 257/E31.127

(57) ABSTRACT

Method for producing back contacts on silicon solar cells and an interconnection between silicon solar cells where the front surface has been fully treated and the back surface has been processed to the point where the said solar cells can be contacted on the back surface. The method further includes: a) attaching the solar cells onto a transparent superstrate, thereby forming a structure, b) depositing a passivating layer onto the back surface of the structure, c) depositing a silicon material layer onto the back surface of the structure, d) separating the silicon material layer by first areas, e) providing contact sites in areas, f) depositing a metal layer onto the back surface of the structure, g) heating the structure to form silicide, h) optionally opening the metal layer in areas, and i) depositing metal onto the silicide. Device includes solar cells with back contacts and interconnections produced by the method.

### FIELD OF THE INVENTION

The present invention relates to a method for simultaneously producing separated back contacts on solar cells and interconnection between silicon solar cells.

### BACKGROUND

Currently the processes of solar cell manufacture and interconnecting solar cells in solar modules are two very separate processes. In a first process the solar cells are fully finalized with contacts and in a second process require additional metallization steps to connect a series of solar cells in a module. This creates challenges with respect to alignment of the solar cells and possible cells breakage during contacts soldering.

This invention describes a method by which the back contact of back junction solar cells can be fabricated simultaneously with the solar cell interconnects.

The present invention seeks to tackle the abovementioned challenges by providing a structured silicon surface where all non-silicon surfaces will become contact separation areas while the silicon surfaces will become the basis of the metal conductors. Preferably the non-silicon surfaces are provided by a reflective material.

### PRIOR ART

Patent application WO 2008/039078 A2 describes a cost efficient method of a back contact silicon solar cell. In the method, an aluminum back contact is applied on the whole back surface and later the contacts are separated by appropriate method.

Patent application WO2006/110048 A1 describes a method for employing a passivation layer structure consisting of an amorphous silicon bottom layer and an amorphous silicon nitride top layer. The patent application WO2006/110048 A1 is silent about patterning the passivating layer.

### SUMMARY OF THE INVENTION

Method for producing back contacts on silicon solar cells and an interconnection between silicon solar cells where the front surface has been fully treated and the back surface has been processed to the point where the said solar cells can be contacted on the back surface. The method further comprises:
a) attaching the solar cells onto a transparent superstrate, thereby forming a structure
b) depositing a passivating layer onto the back surface of the structure
c) depositing a silicon material layer onto the back surface of the structure
d) separating the silicon material layer by first areas
e) providing contact sites in second areas
f) depositing a metal layer onto the back surface of the structure
g) heating the structure to form silicide
h) optionally opening the metal layer in third areas
i) depositing metal onto the silicide

According to the invention there is also provided a solar cell module comprising back contacts and interconnections produced by the method according to the invention.

### OBJECTIVE OF THE INVENTION

The main objective of the invention is to provide an efficient method of simultaneously producing locally defined contacts on back contacted silicon solar cells and an interconnection between silicon solar cells located on a module superstrate.

The objective of the invention may be achieved by the features as set forth in the description below and in the appended claims and attached figures.

### DESCRIPTION OF THE INVENTION

The present invention relates to producing a back contact structure for back-junction silicon solar cells and an interconnection between a series of cells, where the method comprises applying a silicon solar cell, which is typically doped p-type or n-type with a base concentration of dopants, with doped regions of p-type and/or n-type conductivity, the method comprises depositing a passivating layer onto the silicon solar cell and using a structured silicon surface as the basis to form separated metal contacts.

The present invention further relates to a method of attaching silicon solar cells on a module superstrate and producing a patterned back contact structure on the back side of said silicon solar cells and simultaneously producing the interconnection between said silicon solar cells by use of low temperature silicide formation.

The invention may employ any silicon wafer or silicon thin film. This includes wafers or thin films of monocrystalline silicon, microcrystalline silicon, nanocrystalline silicon and multicrystalline silicon and any known and conceivable configuration of the p-doped and n-doped regions on the back side.

The term “front side” denotes the side of the solar cell that is exposed to the sunlight. The term “back side” is the opposite side of the front side, and the term “back-contacted” means that all connectors are placed on the back side of the solar cell.

The term “p-doped region” means a surface area of the solar cell where a doping material resulting in an increased number of positive charge carriers is added into the silicon material within a certain distance below the surface forming a region of the solar cell with a surface layer with p-type conductivity. The term “n-doped region” means a surface area of the solar cell where a doping material resulting in increased number of negative charge carriers (mobile electrons) is added into the silicon material within a certain distance below the surface forming a region of the wafer with a surface layer with n-type conductivity.

The present invention relates to a method for producing back contacts on silicon solar cells and an interconnection between silicon solar cells where the front surface has been fully treated and the back surface has been processed to the point where the said solar cells can be contacted on the back surface. The method further comprises:
a) attaching the solar cells onto a transparent superstrate, thereby forming a structure
b) depositing a passivating layer onto the back surface of the structure
c) depositing a silicon material layer onto the back surface of the structure
d) separating the silicon material layer by first areas
e) providing contact sites in second areas
f) depositing a metal layer onto the back surface of the structure
g) heating the structure to form silicide
h) optionally opening the metal layer in third areas
i) depositing metal onto the silicide

The present invention also relates to a device comprising solar cells with back contacts and interconnections produced by the above mentioned method.

The term “silicon material” denotes any silicon containing material that will form metal silicide with the deposited metal layer 109 upon the appropriate thermal treatment. This comprises crystalline silicon, amorphous silicon, micro-crystalline silicon and nano-crystalline silicon. The silicon material may contain 0-40 atomic percent hydrogen. The silicon material may be intrinsic or doped n-type or p-type with dopant concentrations varying from 0-10²¹ cm⁻³.

The term “exposed silicon surface” denotes silicon material that is exposed to the ambient.

The term “contact site” hereby means an area on the surface of the solar cell where the solar cell is to be contacted. This said area can reside on an n-doped region, a p-doped region, n-type silicon material or p-type silicon material.

The term “providing a contact site” denotes processing the structure in such a way that between the contact site and the metal layer to be deposited, there only resides silicon material on top of the contact site. The important point is that regardless of the prior steps, there should only reside silicon material at the contact site.

The term “silicide” denotes a compound that has silicon together with more electropositive elements. These elements can typically be, for example nickel, palladium, titanium, silver, gold, aluminium, copper, tungsten, vanadium, chromium.

The term “solar cell” denotes an appropriately doped silicon substrate of one type of conductivity with at least one doped region of the other type of conductivity, regardless of whether it has been provided with contacts or interconnection, or not.

The term “structure” denotes the device at any process step.

Back-contacted solar cells should have at least one doped region, which is doped oppositely of the substrate doping, on its back side, but typically there will be several doped regions with alternating conductivity in an interdigitated pattern.

This invention provides a method for simultaneously producing a back contact structure for a solar cell and the interconnection between solar cells placed on a module superstrate, regardless of front surface treatment and back surface treatment prior to application of the method described in this document. The invention further relates to a back contact structure and a solar cell including the back contact structure.

In more detail, the invention relates to a structure 120 comprising silicon solar cells 100 that have received full front surface treatment and fabricated in such a way that they can be back-contacted.

The method of the invention can employ any silicon material substrate manufactured into a solar cell in such a way that it can be back contacted, regardless of the techniques and methods used.

In the figures the drawings are made in such a way that the front side faces the bottom of the page and the back side faces the top of the page. The drawings are schematic and are not to scale. The attached figures show embodiments of the invention.

### SHORT DESCRIPTION OF THE FIGURES

The invention will be described in detail below, with reference to the enclosed drawings which show embodiments of the invention where:

FIGS. 1a-e schematically illustrate the first embodiment of the method according to the invention

FIGS. 2a-e schematically illustrate the second embodiment of the method according to the invention

FIGS. 3a-f schematically illustrate the third embodiment of the method according to the invention

FIGS. 4a-f schematically illustrate the fourth embodiment of the method according to the invention

### DETAILED DESCRIPTION OF THE INVENTION

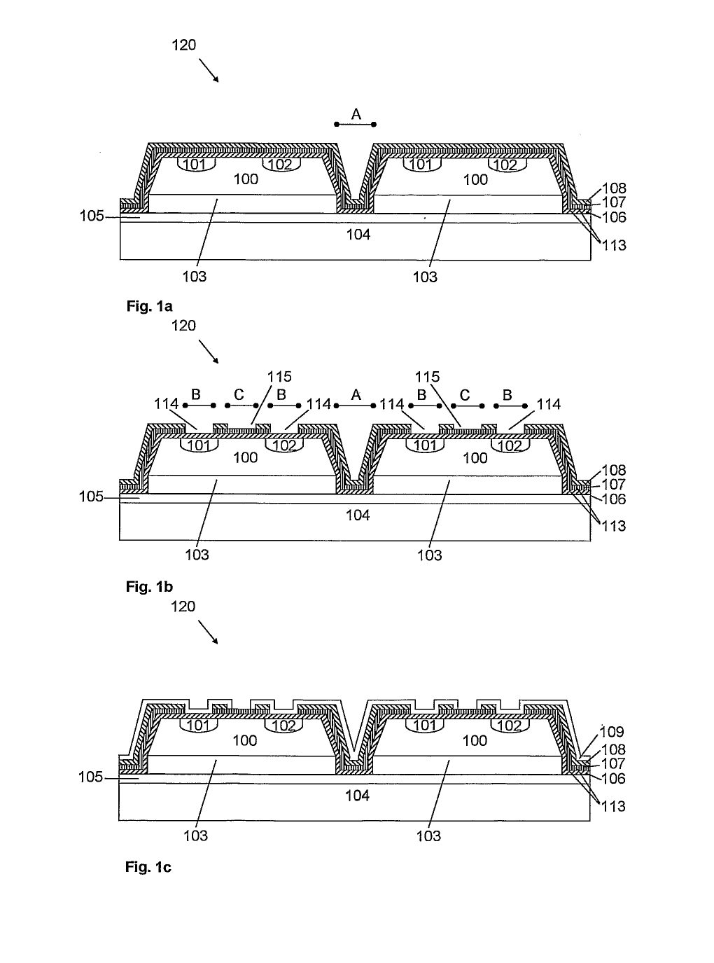

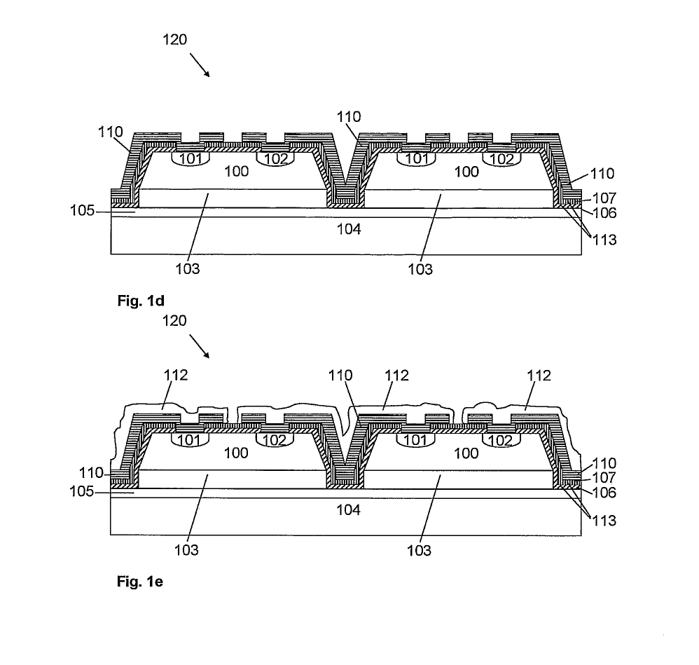

Solar cells 100 are placed front side down on a module superstrate 104 and attached to this module superstrate 104 by an attachment layer 105. This is shown e.g. in FIG. 1a. The attachment layer 105 can typically comprise a transparent adhesive or a thermoplastic material which becomes adhesive upon thermal treatment. The attachment can for example be done by applying a transparent adhesive onto the module superstrate 104, the front side of the silicon solar cell 100 or both. The attachment layer 105 may or may not reside in the areas A between the solar cells, depending on the application method.

When the solar cells 100 are ready for back side treatment, a passivating layer 113 is deposited on the whole structure 120, including the areas A between the solar cells 100.

Alternatively the passivating layer 113 can be applied to the back side of the solar cell 100 prior to attachment to the module superstrate 104. In this case the passivating layer 113 will not reside in areas A between the solar cells 100.

The passivating layer 113 can typically comprise an amorphous silicon bottom layer 106 onto which an amorphous silicon nitride layer 107 in deposited.

If the passivating layer 113 is a double layer stack, the bottom layer 106 can typically comprise amorphous silicon carbide, amorphous silicon oxide, amorphous silicon nitride, aluminum oxide, amorphous silicon, micro-crystalline silicon or nano-crystalline silicon. The top layer 107 can typically comprise amorphous silicon carbide, amorphous silicon oxide, amorphous silicon nitride or aluminum oxide.

The passivating layer 113 can also comprise of one single layer such as for example amorphous silicon carbide, amorphous silicon oxide, amorphous silicon nitride, aluminum oxide or a silicon material.

The passivating layer 113 is not restricted in any way to the above mentioned materials. The passivating layer 113 is not restricted to a single layer or double layer. It can also comprise three or more layers.

Onto the structure 120 it is deposited a silicon material layer 108 such that it covers the passivating layer 113 and the regions A between the solar cells 100.

In the case where the passivating layer 113 is a single layer comprising silicon material, then the passivating layer 113 and the silicon material layer 108 is in fact only one layer of silicon material. In this case the deposition of the passivating layer 113 and the deposition of the silicon material layer 108 are in fact done simultaneously.

Typically, the next step is providing a contact site in areas B, as described above.

In the case where the passivating layer 113 comprises a non-silicon material, for example amorphous silicon nitride, the said non-silicon material layer needs to be fully removed in areas B. This can be done prior to deposition of the silicon material layer 108 or after the deposition of the silicon material layer 108.

In the case where the passivating layer 113 and the silicon material layer 108 is in fact the same, single layer, as described above, a contact site has then already been provided.

In the embodiments of the method of the invention described below, the passivating layer 113 comprises an amorphous silicon layer 106 and an amorphous silicon nitride layer 107. Furthermore, the silicon material layer 108 comprises amorphous silicon.

In the case where the passivating layer 113 comprises amorphous silicon carbide, amorphous silicon oxide, amorphous silicon nitride, amorphous silicon, micro-crystalline silicon or nano-crystalline silicon, the passivating layer can be deposited by plasma enhanced chemical vapor deposition (PE-CVD), hot wire CVD (HW-CVD), expanding thermal plasma CVD (ETP-CVD), electron cyclotron resonance (ECR), sputtering or other appropriate technique.

Aluminum oxide can be deposited by atomic layer deposition (ALD).

Typical thickness of the passivating layer 113 is 1-1000 nm, preferably 5-200 nm and most preferably 10-150 nm.

The next step is typically patterning the exposed silicon surface by either removing the silicon material layer 108 in areas C or applying a non-silicon material 116 onto the silicon material layer 108 in areas C. A non-silicon material would typically be a reflection enhanced material, for example a polymer or a resin comprising reflection enhancing additives. The reflection enhanced material is typically applied by ink jetting or screen printing.

In the case where the patterning of the exposed silicon surface is carried out by removing the silicon material layer 108 in areas C, this removal can typically be carried out by ink jet etching or laser ablation.

In addition to the techniques described above, the silicon material layer 108 can be deposited by ink jetting. In this case the deposition and the patterning of the exposed silicon surface are done simultaneously.

In two embodiments of the method of the invention a metal layer 109 is then deposited by a selective deposition technique such that the metal only deposits on the exposed silicon surface. Typically this will be in all areas except in areas C. This step results in the cells being back contacted and being interconnected with each other.

Selective deposition techniques of the metal layer 109 may comprise electroless plating or electro plating. Alternatively, the metal deposition step may comprise evaporation or sputtering through a mask.

In two other embodiments of the method of the invention the metal layer 109 is deposited by a non-selective method, such as sputtering or evaporation. In this case, the metal layer 109 is deposited on the whole of the structure 120.

After the metal layer 109 has been applied, the structure 120 is subjected to the appropriate annealing step in order to facilitate the formation of silicide 110 where the metal layer 109 is in contact with the silicon material, which is essentially in all areas except areas C. Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

In the case where the metal layer 109 has been deposited by a non-selective method, as described above, the metal that has not formed silicide (the excess metal), should be removed in order to separate the contacts. This can typically be done by utilizing an etching solution which has a high selectivity. Hence, the etch rate for etching the excess metal 109 is significantly larger than the etch rate for etching the silicide 110. This solution can comprise of nitric acid or a mixture of nitric acid and hydrofluoric acid.

In the case where the exposed silicon surface has been patterned by applying a reflective layer 116 onto the silicon material layer 108 and the excess metal 109 is to be removed by the above mentioned chemical treatment, the reflective layer 116 should withstand the said chemical treatment to such an extent that the said reflective layer 116 resides in areas C after the said chemical treatment.

To increase the electrical conductivity of the silicide contacts 110 a metal 112 is deposited onto the silicide contacts 110 by, for example, electroplating. Typically the deposited metal comprises copper.

### EMBODIMENTS OF THE INVENTION

It should be noted that the invention is not limited to these embodiments below, but can be varied within the scope of the claims below. It should also be noted that the elements of some of the embodiments may readily be combined with elements of other embodiments.

### First Embodiment

The first embodiment of the method of the invention is illustrated by FIGS. 1a-1e.

The first embodiment of the method of this invention has as a starting point a silicon solar cell 100. The silicon solar cell 100 can be p-type or n-type. The silicon solar cell 100 has been doped to form regions with n-type conductivity 101 and regions with p-type conductivity 102. The silicon solar cell 100 has received full front treatment resulting in a surface region 103 which production method can comprise damage etch, surface texturing, and surface passivation. FIG. 1a shows two silicon solar cells 100 that have been placed with the front side faced down on a module superstrate 104 onto which an attachment layer 105 has been applied.

Area A in FIG. 1a refers to the area between the solar cells that are to be interconnected.

The back surface might be planar or textured, e.g. by wet chemistry or plasma treatment.

The structure 120 is first cleaned for example by exposure to a mixture of H₂S0₄ and H₂0₂, a mixture of HCl, H₂0₂ and H₂0, or a mixture of NH₄0H, H₂0₂ and H₂0, followed by an oxide removal, e.g. in diluted HF.

Onto the structure 120, i.e. the back side of the silicon solar cells 100 and in the area A between the solar cells 100, a hydrogenated amorphous silicon (a-Si:H) layer 106 is deposited. Onto the a-Si:H layer 106 a hydrogenated amorphous silicon nitride a-SiNₓ:H layer 107 is deposited. These two layers will constitute a passivation layer 113.

Typical thickness of the passivating layer 113 is 1-1000 nm, preferably 5-200 nm and most preferably 10-150 nm.

The passivating layers 106 and 107 can be applied using plasma enhanced chemical vapor deposition (PE-CVD) or other deposition techniques suitable for this purpose such as hot wire CVD (HW-CVD), expanding thermal plasma (ETP), electron cyclotron resonance (ECR), sputtering or similar techniques.

Onto the a-SiNₓ:H layer 107 there is deposited an a-Si:H layer 108 using the same technique as used for the previous steps. This layer will act as a seed layer for subsequent metal layer deposition. This step can either be applied using the methods mentioned above and can be carried out separately or in the same process sequence as the application of the passivating layer. The structure 120 at this step is shown in FIG. 1a.

Subsequently, in areas B, the a-Si:H layer 108 and the a-SiN:H layer 107 are removed while at least some of the a-Si:H layer 106 remains intact, thus providing contact sites in areas B.

This can be done by ink jet etching, laser ablation, screen print etching or applying a patterned etch mask, then etching and subsequently removing the etch mask.

Similarly, in areas C the a-Si:H layer 108 is removed while at least some of the a-SiNₓ:H layer 107 will remain, forming a pattern of openings 115 where no metal shall be deposited and therefore define the contact separation. Thus performing the process of separating the silicon material layer 108 by a first area C. See FIG. 1b.

Then a metal layer 109 is applied by a selective deposition technique in such a way that metal only deposits on the surfaces that is covered by a-Si:H, i.e. the exposed silicon surface. That is, the metal is essentially deposited everywhere except areas C, as seen in FIG. 1c, and forms the regions which later shall form silicide.

This method can constitute electroplating or electroless plating. Alternatively, this method can constitute evaporation through a mask or sputtering though a mask.

Suitable metals for electroplating and electroless plating include nickel, palladium, silver, gold, chromium, tin, or any combination of these materials. The invention is not restricted to these choices of metals, it may apply using any material that forms a conductive silicide or silicon alloy with silicon material resulting in an ohmic contact between the silicide or silicon alloy and the silicon material.

As seen from FIG. 1c, the metal is deposited in such a way that is forms an interconnection between a contact site of one polarity on one solar cell with the contact site of the other polarity of another solar cell. Hence, the contacting scheme of the individual cells is manufactured simultaneously with the interconnection between the solar cells.

After the metal layer 109 has been applied, the structure 120 is subjected to the appropriate annealing step in order to facilitate the formation of silicide 110 where the metal layer 109 is in contact with the silicon material (FIG. 1d). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

To increase the electrical conductivity of the contacts and interconnects 110, a metal 112 in deposited onto the silicide by, for example, electroplating. (See FIG. 1e). It should be noted that in FIG. 1e there is a discontinuity in the metal layer 112 in areas C which results in a separation of the contacts.

### Second Embodiment

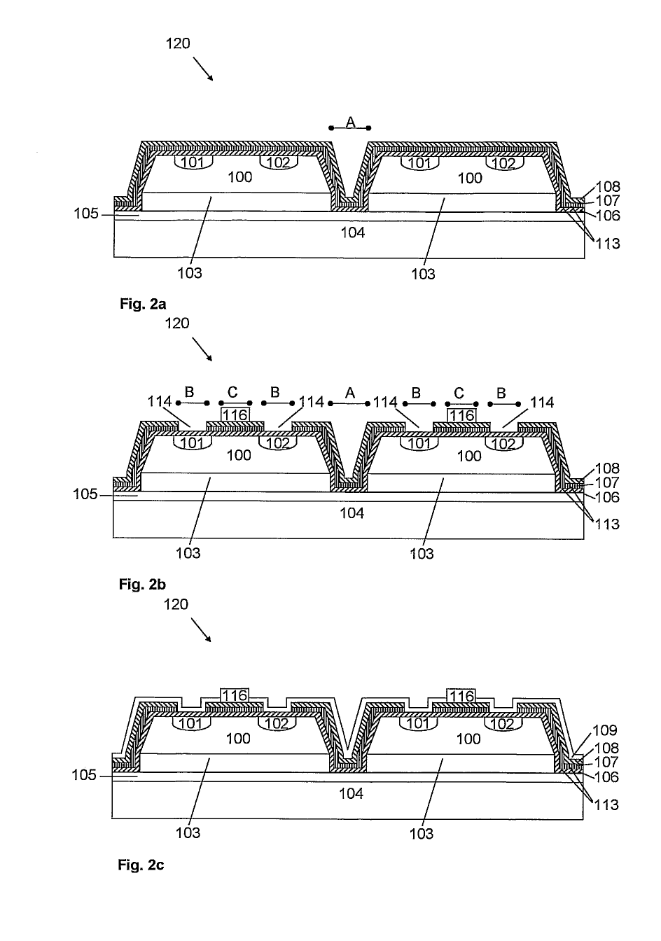

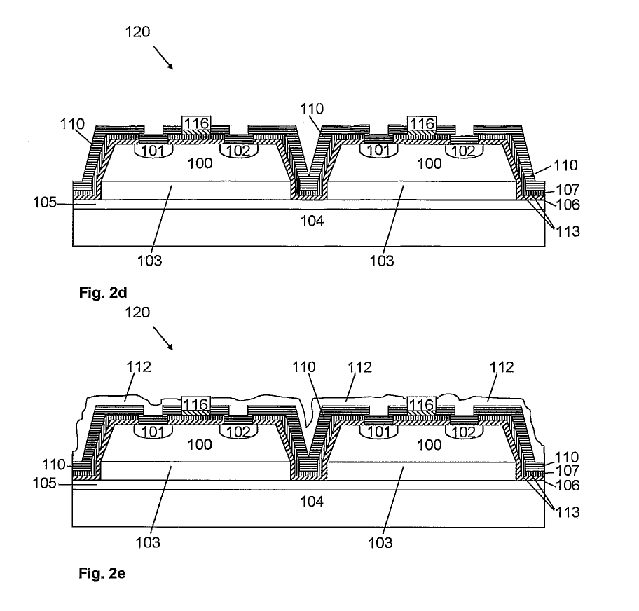

The second embodiment of the method of the invention has the same starting point as in the first embodiment as seen in FIG. 2a.

After the application of the a-Si:H layer 108, the a-Si:H layer 108 and the a-SiNₓ:H layer 107 are removed in areas B, while at least some of the a-Si:H layer 106 in areas B remains intact, thus providing contact sites in areas B.

This can be done by ink jet etching, laser ablation, screen print etching or applying a patterned etch mask, then etching and subsequently removing the etch mask.

Then a reflective material 116 is applied in areas C by ink jetting, screen printing or other appropriate technique. The areas in which the reflective material 116 is applied define the areas in which no metal contact should reside, thus performing the process of separating the silicon material layer 108 by a first area C, as seen in FIG. 2b.

The reflective layer 116 material can typically comprise a resin or a polymer that in turn comprises reflection enhancing additives, such as titanium oxide particles.

The reflective material 116 may need curing at by using slightly elevated temperatures or by optical treatment, such as exposure to ultraviolet light.

The purpose of the reflective material is:
to allow the separation of the solar cell contacts and interconnects, and
to enhance the back side reflection of the solar cell and hence increase the solar cell current.

The order of the two last process steps (opening the passivation layer and application of the reflective material) is not necessarily important.

After applying the reflective material 116 a metal layer 109 is applied by any selective deposition technique as explained in the first embodiment of the invention and seen in FIG. 2c. The metal layer 109 is only deposited on the exposed silicon surfaces.

After the metal layer 109 has been applied, the structure 120 is subjected to the appropriate annealing step in order to facilitate the formation of silicide 110 where the metal layer 109 is in contact with the silicon material (FIG. 1d). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

To increase the electrical conductivity of the silicide contacts and interconnects 110, a metal 112 in deposited onto the silicide 110 by, for example, electroplating. (See FIG. 2e). It should be noted that in FIG. 2e there is a discontinuity in the metal layer 112 in areas C which results in a separation of the contacts.

### Third Embodiment

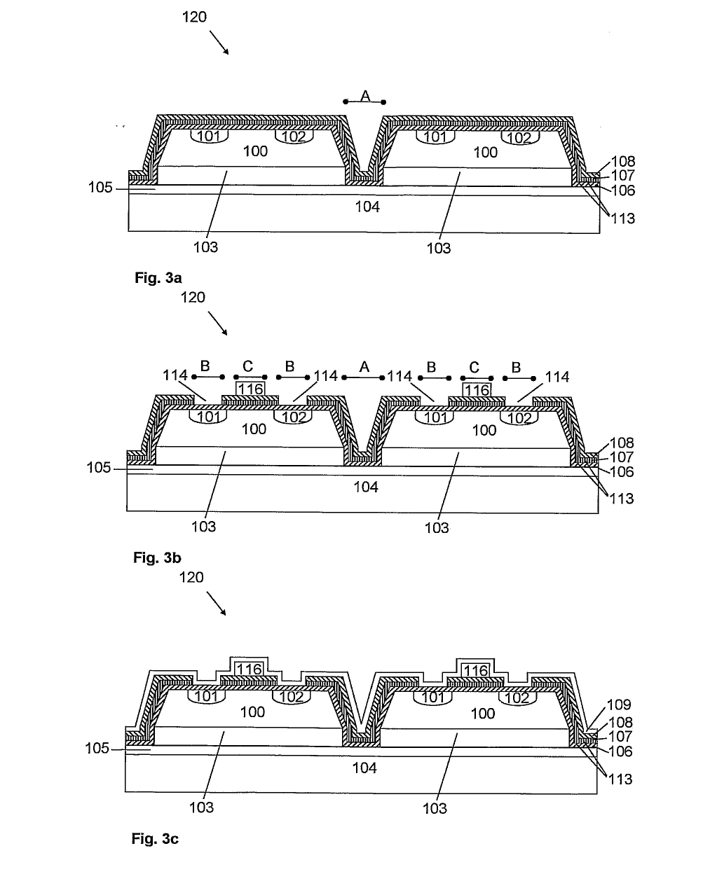

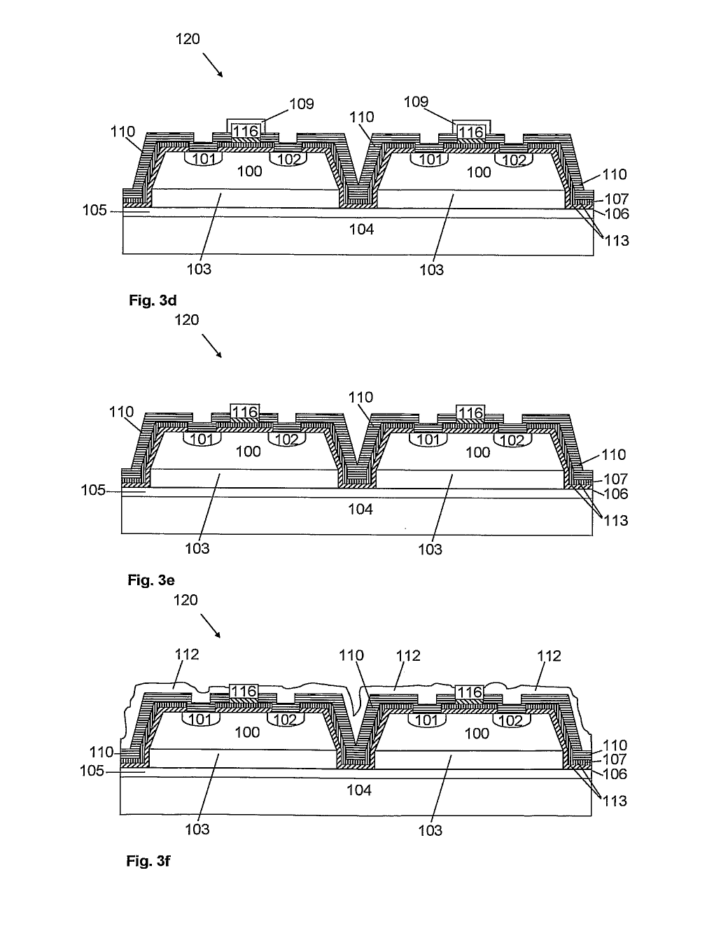

The third embodiment has the same starting point as the second embodiment up to the deposition of the metal, as seen in FIGS. 3a and 3b.

In the third embodiment of the invention, the metal layer 109 is deposited by a non selective technique, such as evaporation or sputtering, resulting in a metal layer 109 which covers the whole structure 120, as seen in FIG. 3c.

Suitable metals for evaporation and subsequent silicide formation include nickel, palladium, titanium, silver, gold, aluminium, tungsten, vanadium, chromium, or any combination of these metals

After the metal layer 109 has been applied, the structure 120 is subjected to the appropriate annealing step in order to facilitate the formation of silicide 110 where the metal layer 109 is in contact with the silicon material (FIG. 3d). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

The next step is to separate the contacts at areas C as seen in FIG. 3e. This can be done by laser ablation of the metal layer 109 which has not formed silicide 109. Alternatively, this can be done by utilizing an etching solution which has a high selectivity. Hence, the etch rate for etching the excess metal 109 is significantly larger than the etch rate for etching the silicide 110. This solution can typically comprise of nitric acid or a mixture of nitric acid and hydrofluoric acid.

The reflective material 116 must withstand the selective etch to such an extent that it does not disappear during the selective etch process nor disperse the etched reflective material to any other parts of the structure 120.

To increase the electrical conductivity of the contacts and interconnects 110, a metal 112 in deposited onto the silicide by, for example, electroplating. (See FIG. 3f). It should be noted that in FIG. 3e there is a discontinuity in the metal layer 112 in areas C which results in a separation of the contacts.

### Fourth Embodiment

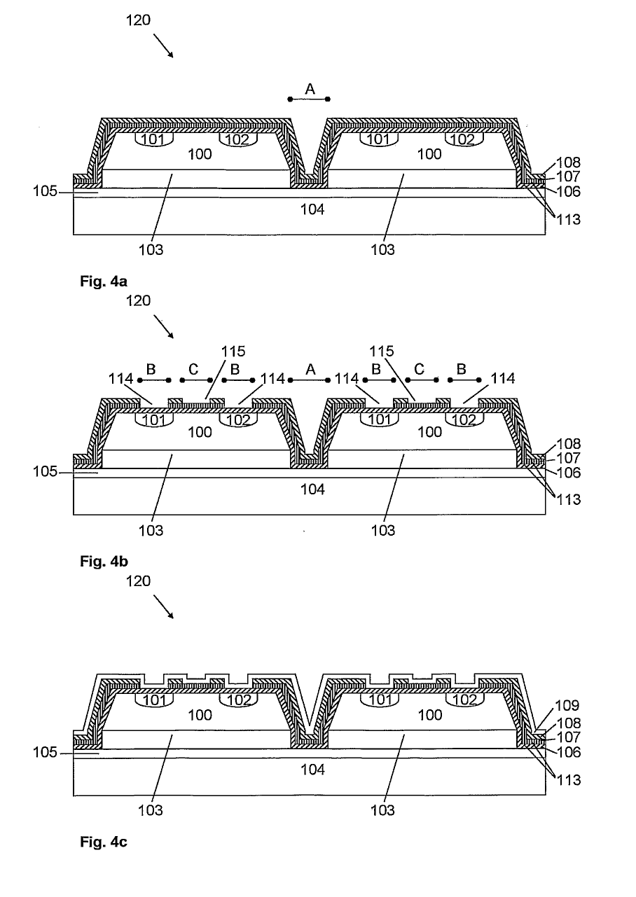

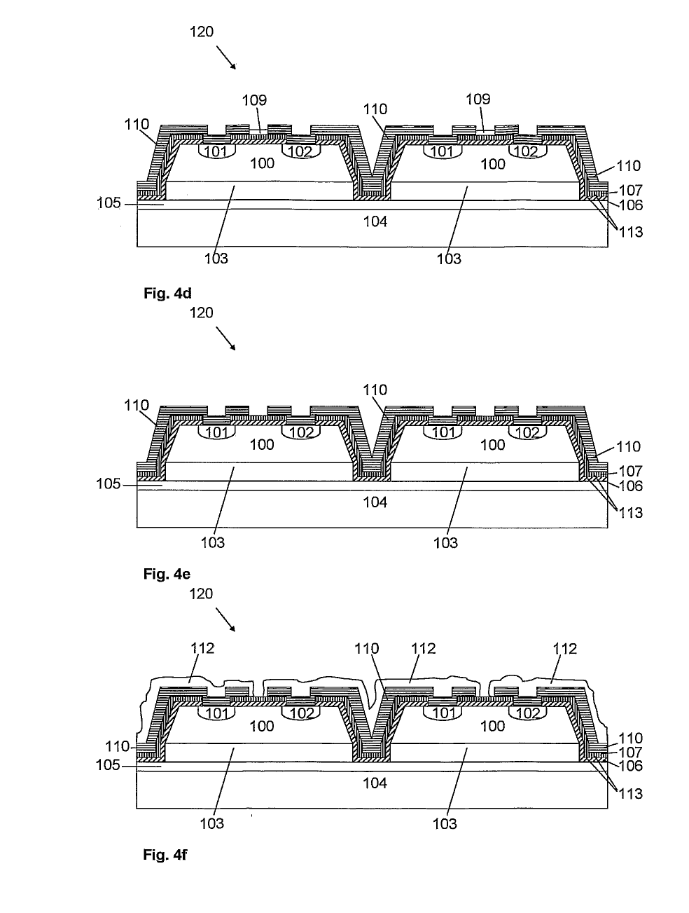

The fourth embodiment has the same starting point as the first embodiment up to the deposition of the metal, as seen in FIGS. 4a and 4b.

In the fourth embodiment of the invention, the metal layer 109 is deposited by a non selective technique, such as evaporation or sputtering, resulting in a metal layer 109 which covers the whole structure 120, as seen in FIG. 4c.

After the metal layer 109 has been applied, the structure 120 is subjected to the appropriate annealing step in order to facilitate the formation of silicide 110 where the metal layer 109 is in contact with the silicon material (FIG. 4d). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

The next step is to separate the contacts at areas C as seen in FIG. 4e. This can be done by laser ablation of the metal layer 109 which has not formed silicide 109. Alternatively, this can be done by utilizing an etching solution which has a high selectivity. Hence, the etch rate for etching the excess metal 109 is significantly larger than the etch rate for etching the silicide 110. This solution can typically comprise of nitric acid or a mixture of nitric acid and hydrofluoric acid.

To increase the electrical conductivity of the contacts and interconnects 110, a metal 112 in deposited onto the silicide by, for example, electroplating. (See FIG. 4f). It should be noted that in FIG. 4e there is a discontinuity in the metal layer 112 in areas C which results in a separation of the contacts.

The method of the invention is in no way restricted to the processes described in the embodiments.

1. Method for producing back contacts on silicon solar cells and an interconnection between silicon solar cells where the front surface has been fully treated and the back surface has been processed to the point where the said solar cells can be contacted on the back surface
wherein said method comprises
a) attaching the solar cells onto a transparent superstrate, thereby forming a structure,
b) depositing a passivating layer onto the back surface of the structure,
c) depositing a silicon material layer onto the back surface of the structure,
d) separating the silicon material layer by first areas (C),
e) providing contact sites in areas (B),
f) depositing a metal layer onto the back surface of the structure,
g) heating the structure to form silicide, and
h) depositing metal onto the silicide.

2. Method according to claim 1,
wherein that step d) of separating the silicon material layer comprises opening said area (C) to such an extent that the exposed silicon surface in said area (C) is removed.

3. Method according to claim 1,
wherein step d) of separating the silicon material layer is performed by depositing a patterned reflective material on the said area (C).

4. Method according to claim 1, wherein step b) and c) can be done simultaneously.

5. Method according to claim 1, wherein step a) is performed after step b).

6. Method according to claim 1, wherein step c) and d) is performed simultaneously.

7. Method according to claim 1, wherein step e) is performed before step c).

8. Method according to claim 1,
wherein the passivating layer is an amorphous silicon layer and an amorphous silicon nitride layer deposited onto the amorphous silicon layer.

9. Method according to claim 8, wherein step e) is performed by removing at least the silicon nitride layer.

10. Method according to claim 1,
wherein the deposition of the metal layer in step f) is performed by electroless plating, electroplating, evaporation through a mask or sputtering though a mask.

11. Method according to claim 1,
wherein depositing the metal in step h) is performed by electro plating of copper.

12. Device comprising back contacts and interconnections wherein the back contacts and interconnections are provided by a method as set forth in claim 1.

13. Method for producing back contacts on silicon solar cells and an interconnection between silicon solar cells where the front surface has been fully treated and the back surface has been processed to the point where the said solar cells can be contacted on the back surface
wherein said method comprises
a) attaching the solar cells onto a transparent superstrate, thereby forming a structure,
b) depositing a passivating layer onto the back surface of the structure
c) depositing a silicon material layer onto the back surface of the structure,
d) separating the silicon material layer by first areas (C),
e) providing contact sites in areas (B),
f) depositing a metal layer onto the back surface of the structure,
g) heating the structure to form silicide,
h) opening the metal layer in areas (C), and
i) depositing metal onto the silicide.

14. Method according to claim 13,
wherein step d) of separating the silicon material layer comprises opening said area (C) to such an extent that no silicon material resides in said area (C).

15. Method according to claim 13,
wherein step d) of separating the silicon material layer comprises depositing a patterned reflective material on the said area.

16. Method according to claim 13, wherein step b) and c) can be done in the same step.

17. Method according to claim 13, wherein step a) is performed after step b).

18. Method according to claim 13, wherein step c) and d) is performed simultaneously.

19. Method according to claim 13, wherein step e) is performed before step c).

20. Method according to claim 13,
wherein the passivating layer comprises an amorphous silicon layer and an amorphous silicon nitride layer deposited onto the amorphous silicon layer.

21. Method according to claim 20,
wherein step e) comprises removing at least the silicon nitride layer.

22. Method according to claim 13,
wherein opening the metal layer in step h) is performed by laser ablation of the metal layer in areas (C).

23. Method according to claim 13,
wherein the metal layer in step h) is performed by exposing the structure to a selective etch.

24. Method according to claim 13,
wherein depositing the metal in step i) is performed by electro plating of copper.

25. Device comprising solar cells comprising back contacts and interconnections wherein the back contacts and interconnections are provided by a method as set forth in claim 13.
